(19) United States
(12) Patent Application Publication
(10) Pub. No.: US 2018/0001139 A1
(43) Pub. Date: Jan. 4, 2018

(54) ACCELERATED PATTERN RECOGNITION IN ACTION SPORTS

(71) Applicants: Stephanie Moyerman, Phoenix, AZ (US); Tyler Fetters, Hillsboro, OR (US); James Brian Hall, Tucson, AZ (US)

(72) Inventors: Stephanie Moyerman, Phoenix, AZ (US); Tyler Fetters, Hillsboro, OR (US); James Brian Hall, Tucson, AZ (US)

(21) Appl. No.: 15/197,097

(22) Filed: Jun. 29, 2016

(51) Int. Cl. A63B 24/00; G01C 19/00; G01P 15/00; G01R 33/02

(52) U.S. Cl. CPC A63B 24/0006; G01R 33/02; G01C 19/00; G01P 15/00

(57) ABSTRACT

Systems and techniques for accelerated pattern matching in action sports are described herein. A plurality of data sets may be collected from a data stream received from a sensor array. Each data set of the plurality of data sets may be compressed into a magnitude value. A first mean and a first standard deviation may be determined for a first set of magnitude values corresponding to a first time period. A second mean and a second standard deviation may be determined for a second set of magnitude values corresponding to a second time period. A mean ratio may be calculated for the first mean and the second mean and a standard deviation ratio may be calculated for the first standard deviation and the second standard deviation. A start point for an action may be generated by determining that the mean ratio and the standard deviation ratio are outside a threshold.

### BACKGROUND

Classification of complex motions from captured sensor data may be a complex and computationally costly procedure. While techniques exist for quantifying simple actions, such as step counting, more complex actions may still lack accuracy in quantification. Further, the quantification of simple actions may involve analyzing to a single number (e.g. a number of steps). Algorithms describing the quality of step or length of stride may use algorithms that may be power hungry, as much more data may be analyzed.

### BRIEF DESCRIPTION OF THE DRAWINGS

To easily identify the discussion of any particular element or act, the most significant digit or digits in a reference number refer to the figure number in which that element is first introduced.

FIG. 1 illustrates an environment including an action detection engine for accelerated pattern matching in action sports, according to various embodiments.

FIG. 2 illustrates an example of a sensor hub for accelerated pattern matching in action sports, according to various embodiments.

FIG. 3 illustrates a graph of an example data stream from a sensor array for accelerated pattern matching in action sports, according to various embodiments.

FIG. 4 illustrates an example of a system for accelerated pattern matching in action sports, according to various embodiments.

FIG. 5 illustrates a flowchart of an example of a method for accelerated pattern matching in action sports, according to various embodiments.

FIG. 6 illustrates a flowchart of an example of a method for accelerated pattern matching in action sports, according to various embodiments.

FIG. 7 is a block diagram illustrating an example of a machine upon which one or more embodiments may be implemented.

### DETAILED DESCRIPTION

Motion classification may be a technically complex task. In particular, in action sports such as snowboarding, a participant may be moving down a slope and may interact with a variety of obstacles. The participant may complete a run down the slope and through the obstacles completing a series of complex movements (e.g., jumps, flips, turns, etc.). The run may include segments of relative non-action (e.g., a period of time the participant takes between obstacles, etc.) and segments during which actions (e.g., tricks, etc.) are performed (e.g., an aerial trick completed off of a jump, etc.). Existing techniques for sports tracking and analytics may post-process an entire event or time stream in order to detect that an event has happened. In an action sports context, a participant may perform the entire action before the existing techniques may be able detect that the action has taken place. For example, by the time a jump is detected, the participant may be back on the ground and the action may be complete. Existing techniques may not exist for detecting actions in real-time or near real-time. With the growing popularity of action sports and competitive events highlighting action sports (e.g., X Games, Olympics, etc.), the importance of real-time detection, quantization, and scoring of actions in action sports may increase.

Systems and techniques are disclosed herein for performing real-time and near real-time analytics for action sports. The present subject matter may dramatically improve pattern recognition of actions in action sports from sensor data compared to existing techniques. While examples provided discuss snowboarding, it may be understood that the present subject matter may be applied to many action sports such as, for example BMX ramp, skiing, skateboarding ramp, wakeboarding, etc.

The present subject matter may classify and quantify action sports data in real-time by fusing the sensor data from multiple sensors in a sensor array. Thus, multiple sets of independent sensor data may allow more accurate classification of complex motion combinations (e.g., tricks). For example, an aerial jump may include several dimensions of movement that may be difficult to accurately identify with a single sensor reading. Thus, the present subject matter may employ a sensor array combining a variety of sensors to capture a more robust data set to provide increased accuracy. For example, a user may mount a sensor array to their equipment (e.g., snowboard, skateboard, bike, etc.). Raw data from the sensor array may be streamed via long range radios and fiber optic cable to a central computing hub. Actions may be detected in real-time and near real-time by applying an algorithm to the streaming raw data. For example, a jump pattern may be recognized less than 5 sample point from the start point of the jump. Statistics for an identified action may then be processed in real-time as opposed to being analyzed in post processing. The speed of detection of an action may be as fast as a rate at which data may be read from the sensor (e.g., ˜10-200 milliseconds). Faster sensors may lead to a reduction in detection latency. The present subject matter may increase computational efficiency as the computation time for action detection may be less than the rate at which data may be streamed from the sensors.

The present subject matter may provide a variety of advantages. The present subject matter may provide a dramatic improvement in the speed of pattern recognition in action sports as detection may be completed in near real-time (e.g., as sensor data is collected at the start of a jump, etc.) as opposed to analyzing data after the action has been completed (e.g., after a jump has been landed, etc.). In addition, statistics may be aggregated in real-time and may be used for real-time statistical analysis which may be suitable for a live events or events broadcasted live.

The present subject matter may be hardware scalable because sensors outputting at various frequencies (e.g., ˜50 Hz-400 Hz or more) may be used interchangeably with pattern recognition being accelerated as faster sensors are added. In other words, the speed of pattern recognition increases as sensor data input speed increases.

The present subject matter may result may result in an increase in computational efficiency over existing techniques because the present subject matter employs lightweight algorithms that may be performed on board the sensor array. For example, the compute time may be significantly less than the latency between data samples and may require little memory to process data. The applicability of the present subject matter to increase the speed of pattern recognition across a broad range of action sports may also decrease the use of specialized hardware for individual action sports. For example, the same hardware may be used for snowboarding and skiing.

It may be understood that the present subject matter may be utilized in a variety of situations including, but not limited to, automated real-time coaching feedback, real-time user feedback, enhanced live event data and statistics tracking, scoring, judging, broadcast data and statistics, and real-time trick competitions for athletes at different locations worldwide.

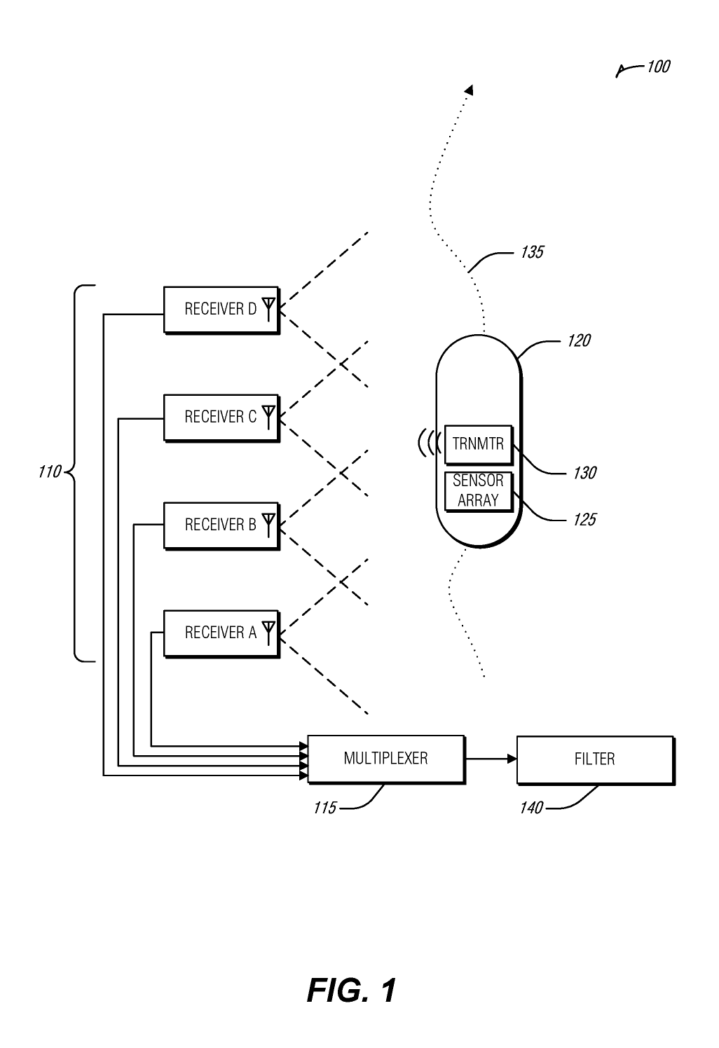

FIG. 1 illustrates an environment 100 including an action detection engine 140, according to various embodiments. The environment 100 may include an action sports course (e.g., a downhill slope for snowboarding, a snowboard terrain park, a ski slope, a skateboard park, a wake board course, etc.). The action sports course may include a set of receivers 110 (e.g., 900 MHz radio receivers, etc.) positioned along a path 135 of a participant (e.g., a snowboarder, skateboarder, wake boarder, skier, etc.)

A sensor array 125 (e.g., a hub including various sensor devices, etc.) may be affixed to a sporting device 120 (e.g., snowboard, skateboard, skis, wake board, etc.) of the participant. For example, a sensor array may be attached to the top of a snowboard. The sensor array 125 may include a variety of sensors such as, for example, an accelerometer, a gyroscope, a magnetometer, a global positioning system (GPS) receiver, a barometer, etc. Each of the sensors may provide a set of data regarding the movement of the sporting device 120 and the environment in which the sporting device 120 is used which may be imputed to the participant.

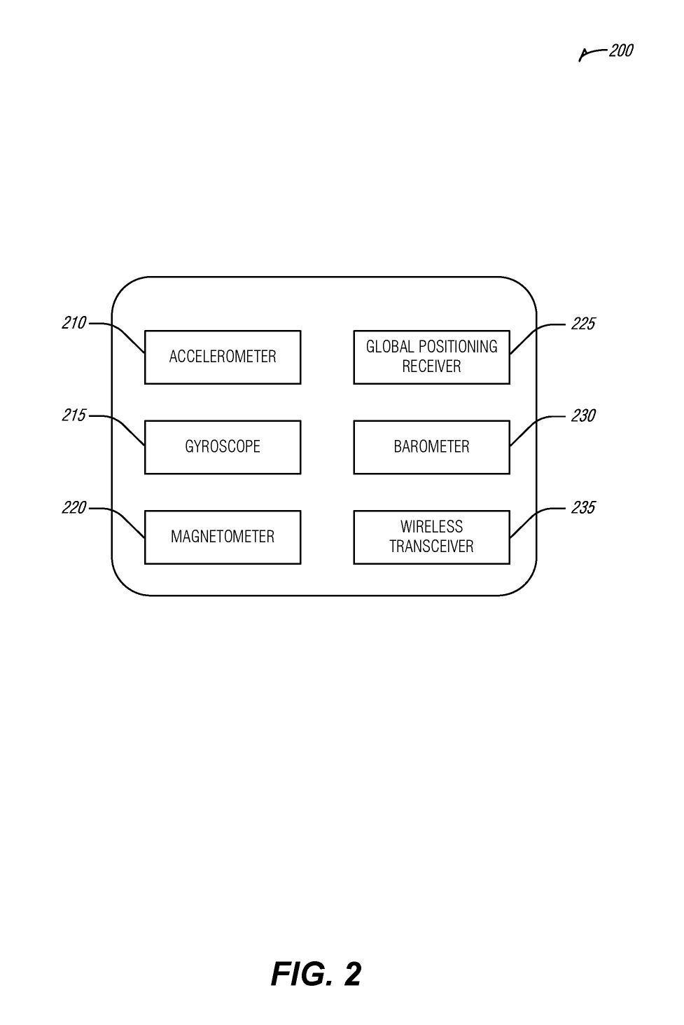

A transceiver 130 (e.g., a 900 MHz wireless transceiver, Wi-Fi transceiver, etc.) may also be affixed to the sporting device 120 of the participant. In some examples, the transceiver 130 may be included in a device including the sensor array 130. The transceiver 130 may be communicatively coupled to the set of receivers 110 (e.g., via wideband radio communication, Wi-Fi, etc.). The transceiver 130 may transmit data from the sensor array 125 to the set of receivers 110 as the participant proceeds through course (e.g., along the path of the participant 135). For example, the transceiver may send sensor data to the set of receivers 110 as the participant proceeds down a course and through and over obstacles. The set of receivers 110 may be arranged along the course in a configuration minimizing the risk of signal loss to ensure a complete set of sensor data is received. In some examples, the location of the set of receivers may be used in analyzing the received data (e.g., to triangulate the participant's position, etc.). In some examples, the sensor array 125 and the transceiver 130 may be combined included in a sensor hub. The sensor hub may be affixed to the sporting device 120. An example of a sensor hub is provided in FIG. 2.

The set of receivers 110 may be communicatively coupled to a multiplexer 115 using a high speed connection (e.g., fiber optic cable, etc.). For example, the multiplexer may act as an aggregation hub acting as a termination point for each receiver of the set of receivers 110. The multiplexer 115 may process data received from the sensor array 125. In some examples, the multiplexer 115 may generate timestamps for the participant's run thorough the action sports course. For example, a sensor may provide data at 1 millisecond (ms) intervals and the multiplexer may assign timestamps for the sensor data at 1 ms intervals. The multiplexer 115 may then generate a single set (or multiple sets) of sensor data for each timestamp.

The multiplexer 115 may discard duplicate sensor data. For example, two acceleration values for along an axis may be received at receiver A and receiver B for the same timestamp and the multiplexer 115 may discard one of the values. The multiplexer 115 may reduce the collected sensor data for the timestamp to a single set. For example, the multiple data sets may be received from the set of receivers 110 and the multiplexer 115 may aggregate the multiple data sets into a single data set. A variety of techniques may be used to determine the single set of sensor data. For example, the multiplexer 115 may average the sensor data received from receiver A and receiver B, discard data points that appear to be outliers (e.g., outside a standard deviation of received data, discard duplicate data points based on the respective geographical locations of receivers (e.g., data points received from receiver B may be preferred over data points received from receiver A for a given timestamp based on the participant's location on the action sports course, etc.).

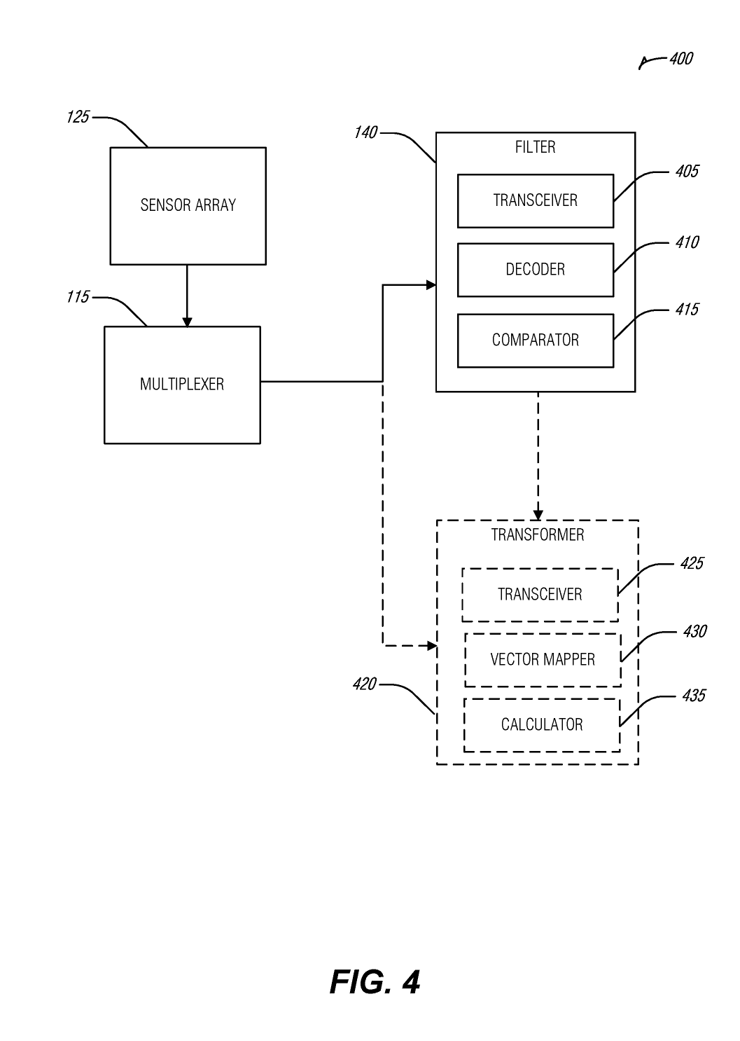

The multiplexer 115 may be communicatively coupled to a filter 140 (e.g., via high speed network, shared physical bus, etc.). The multiplexer 115 may transmit sets of sensor data to the filter 140 along with corresponding timestamps. For example, the multiplexer 115 may provide a data stream including data sets arranged by timestamp. The filter 140 may analyze the set of sensor data to detect the beginning of an action (e.g., a trick, etc.) performed by the participant. The filter 140 is discussed in greater detail in the description of FIG. 4.

FIG. 2 illustrates an example of a sensor hub 200 for accelerated pattern matching in action sports, according to various embodiments. The sensor hub 200 may include a sensor array providing functionality similar to the sensor array 125 as described in FIG. 1. The sensor hub may include a plurality of sensors such as accelerometer 210, gyroscope 215, magnetometer 220, GPS receiver 225, and barometer 230. In some examples, the sensor array 200 may include a transceiver 130 (e.g., 900 MHz radio, etc.).

Data from each sensor of the plurality of sensors may be transmitted using the transceiver 130. For example, the raw data may be streamed over a 900 MHz radio from a sporting device (e.g., a snowboard, skis, skateboard, wake board, etc.) used by a participant of an action sport (e.g., a snowboarder, skier, skateboarder, wake boarder, etc.) to radio receivers along the course (e.g., the set of receivers 110 as described in FIG. 1), which transmit the signal through fiber optic cables to a central hub (e.g., the multiplexer 115 as described in FIG. 1). The raw data streamed from the sensor array may correspond to respective timestamps and the central hub may return a single set of data for each timestamp. In other words, duplicate data may be discarded.

Various sampling frequencies may be employed for each sensor. The sampling frequency of each sensor may be independent from (or the same as) other sensors of the plurality of sensors. For example, raw 3-axis (e.g., x, y, and z axis in a three dimensional coordinate system, etc.) accelerometer (e.g., from accelerometer 210), 3-axis gyroscope (e.g., from gyroscope 215), 3-axis magnetometer (e.g., from magnetometer 220), barometric pressure (e.g., from barometer 230), and temperature data (e.g., from a thermometer included in the sensor array) may be sampled at a sampling frequency of F, where F≧100 Hz, which may provide higher classification accuracy. For example, GPS data including latitude, longitude, speed, and altitude (e.g., from the GPS receiver 225) may be streamed at a lower sampling frequency, F≧5 Hz, which may provide greater data accuracy.

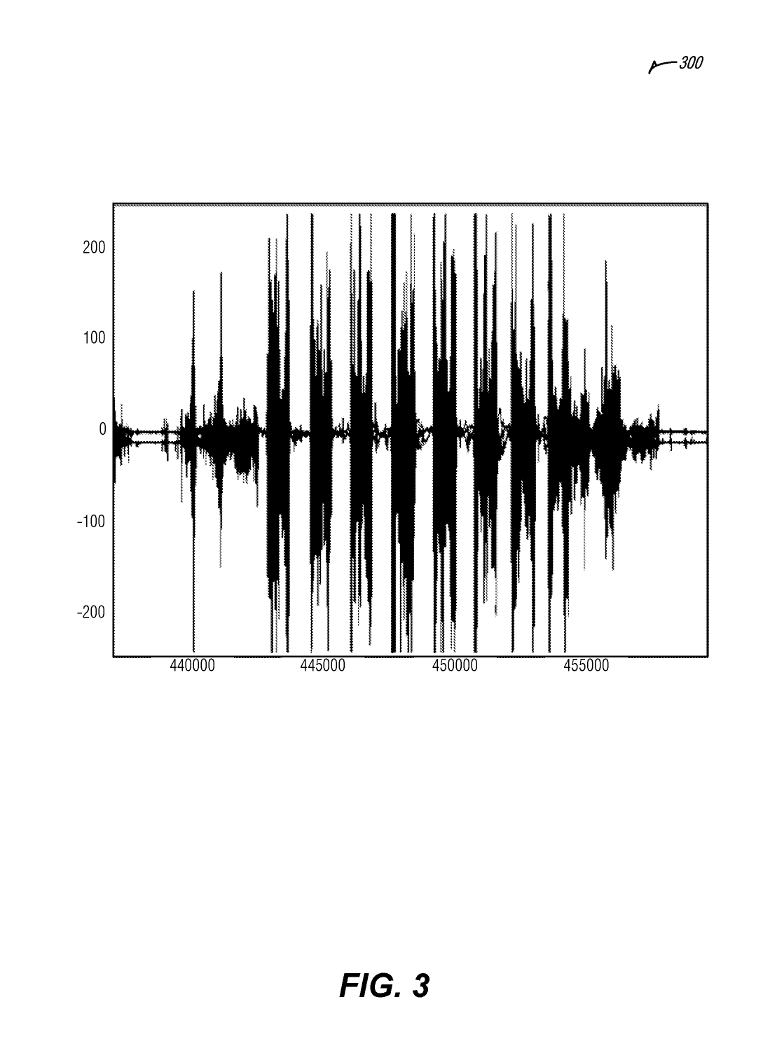

FIG. 3 illustrates a graph 300 of an example data stream from a sensor array (e.g., sensor array 125 as described in FIG. 1, sensor hub 200 as described in FIG. 2, etc.), according to various embodiments. The example data stream may include acceleration data collected from the sensors of the sensor array including, for example, an accelerometer, a gyroscope, and a magnetometer. The graph 300 illustrates a series of peaks and valleys in the sensor data over a period of time. The example set of data may illustrate a run of a participant (e.g., snowboarder, etc.) of an action sport (e.g., snowboarding, etc.). The peaks and valleys may delineate between action segments (e.g., where a trick is being performed, etc.) and non-action segments (e.g., periods between actions, etc.) in the example data stream. The example data stream may be analyzed by a filter (e.g., filter 140) to determine the beginning and end of the action. The example data stream may be analyzed to calculate statistics corresponding to the action (e.g., by the transformer 420 as described in FIG. 4). Additional detail of an action detection and analysis is provided in FIG. 4.

FIG. 4 illustrates an example of a system 400 for accelerated pattern matching in action sports, according to various embodiments. The system 400 may include a sensor array 125 (e.g., as described in FIG. 1) communicatively coupled (e.g., via wireless network, etc.) to a multiplexer 115 (e.g., as described in FIG. 1). The multiplexer 115 may be communicatively coupled to a filter 140. The filter 140 may include a variety of components such as a transceiver 405, a decoder 410, and a comparator 415.

A participant of an action sport (e.g., snowboarding, etc.) may begin a run down a slope including various terrain and obstacle elements. For example, in slopestyle snowboarding, a participant may travel down a slope including a variety of jumps, rails, tabletops, and other terrain elements. In skateboarding a skateboarder may travel through a course including a variety of ramps, rails, table tops, and other terrain elements. The participant may have the sensor array 125 affixed to sporting device used in participation of the action sport. For example, a snowboarder may be completing a run down a slope and performing a variety of actions (e.g., jumps, flips, turns, etc.) with the sensor array 125 affixed to a snowboard. In an example, the sensor array 125 may include an accelerometer, a gyroscope, and a magnetometer. In an example, the sensor array 125 may include a GPS receiver. In an example, the sensor array 125 may include a barometer.

The sensor data from the sensor array 125 may be sent via a wireless transceiver to a set of receivers positioned along the course (e.g., as described in FIG. 1). The sensor data may be received and processed by the multiplexer 115 (e.g., as described in FIG. 1). In some examples, a plurality of data sets from a data stream may be received from the sensor array 125. For example, the plurality of data sets may include a variety of data sets received from various sensors in the sensor array 125 affixed to the snowboard received by the set of receivers.

The transceiver 405 may process incoming data such as the data provided by the multiplexer 115. For example, the incoming data may be data from the sensor array 125 affixed to the snowboard of the snowboarder. A plurality of data sets may be collected by the transceiver 405 from a data stream received from the sensor array 125 (e.g., as provided by the multiplexer 115, etc.). Each data set of the plurality of data sets may correspond to a timestamp.

The transceiver 405 may process data for output from the filter 140. For example, the transceiver 405 may output data to a display (e.g., a display overlay for broadcast television, a webpage, a scoreboard, etc.). The transceiver 405 may forward the incoming data to additional components of the filter 140 such as the decoder 410.

The decoder 410 may evaluate the incoming data to determine a timestamp corresponding to a start of an action (e.g., the beginning of a trick, etc.). In action sports, jumps, trick, and other action may be a small portion of a run. For example, in slopestyle snowboard competition, a snowboarder may ride down a slope including a variety of terrain elements including jumps, rails, etc. A slopestyle run may last 45 seconds including one or more 5 to 8 second trick segments (e.g., segments that should be analyzed carefully) interspersed with segments between the trick segments that may not be fully analyzed. To address the issue of determining which segments of a run should be carefully analyzed, the decoder 410 may identify the start point of an action in real-time or near real-time without regard to speed or orientation of the participant.

Thus, the decoder 410 may compress each data set of the plurality of data sets into a magnitude value. In an example, each data set of the plurality of data sets may be compressed by summing a square magnitude of a first axis, a square magnitude of a second axis, and a square magnitude of a third axis. For example, the accelerometer data may include magnitude along an x-axis, a y-axis, and a z-axis and the squared magnitude for a given timestamp may be calculated using the function x²+y²+z². Thus, each data set may be compressed into a magnitude value. The decoder 410 may then calculate a first mean and a first standard deviation for a first set of squared magnitude values over a first period of time (e.g., a long range timescale, 1 second worth of data, etc.) and a second mean and a second standard deviation for a second set of squared magnitude values over a second period of time (e.g., a short range timescale, <30 ms worth of data, 3 timestamps, etc.).

During periods of non-action (e.g., ground riding, etc.) a set of corresponding squared magnitude values may show high and changing acceleration. During periods of action (e.g., a trick, etc.) a set of corresponding squared magnitude values may show smooth and slow variation in acceleration. The different characteristics of action and non-action segments of a run may be used to determine a start point of an action. Changes in the characteristics of the data in the data stream indicating transition from a non-action segment to an action segment may be detected using means and standard deviations of the magnitude values.

The decoder 410 may determine a first mean and a first standard deviation for a first set of magnitude vales corresponding to a first period of time (e.g., a first timestamp, a first range of timestamps, etc.). The decoder 410 may determine a second mean and a second standard deviation for a second set of magnitude vales corresponding to a second period of time (e.g., a second timestamp, a second range of timestamps, etc.). In an example, the first period of time may be greater than the second period of time. In an example, the first period of time may be one second and the second period of time may be less than thirty milliseconds.

The decoder 410 may calculate a mean ratio for the first mean and the second mean and a standard deviation ratio for the first standard deviation and the second standard deviation. For example, the mean ratio may be calculated using the function Mean_{long}/Meanₛₕₒᵣₜ and the mean standard deviation ratio may be calculated using the function STD_{long}/STDₛₕₒᵣₜ. The mean ration and the standard deviation ratios may indicate when a participant transitions from a non-action segment to an action segment of a run. For example, ratios indicating that the long term data are high while the short term data is low may indicate that the participant has transitioned from a non-action segment to an action segments.

The comparator 415 may compare the mean ratio and the standard deviation. A starting point for an action may be generated based on a determination that the mean ratio and the standard deviation ratio are outside a threshold. In an example, the threshold may be a composite threshold comprising a threshold value for the mean ratio and a threshold value for the standard deviation ratio. In an example, a start point may be generated based on one of the mean ratio and the standard deviation ratio being outside the threshold.

In an example, the determination that the mean ration and the standard deviation are outside the threshold may include determining that the mean ration and the standard deviation have exceeded a threshold for a consecutive set of time periods. For example, the start of the action may be generated when the mean ration and the standard deviation ratio exceed an empirically derived threshold a three consecutive timestamps in a row. This may limit detection time to five consecutive timestamps after the trick has started which may be an improvement of existing techniques. For example, at 400 Hz, the detection of a start of an event may take place 12.5 ms after the start of the event. Thus, detection may occur in near real-time.

In some examples, a first plurality of means and a first plurality standard deviations may be determined for a first plurality of magnitude value sets. Each magnitude set of the first plurality of magnitude value sets may correspond to a first plurality of respective time periods. The plurality of respective time periods may be sequential and may begin prior to the first period of time. A second plurality of means and a second plurality standard deviations may be determined for a second plurality of magnitude value sets. Each magnitude set of the second plurality of magnitude value sets may correspond to a second plurality of respective time periods. The plurality of respective time periods may be sequential and may begin prior to the second period of time. A plurality of mean ratios may be calculated for respective of the first plurality of means and respective of the first plurality of standard deviations and a plurality of standard deviation ratios may be calculated for respective of the second plurality of means and respective of the second plurality of standard deviations. The comparator 415 may identify a starting point for the action by determining that the plurality of mean ratios and the plurality of standard deviation ratios are outside the threshold.

The comparator 415 may detect start events for a variety of action sports such as for example, snowboarding, skiing, skateboarding, wake boarding, etc. by configuring the comparator 415 with one or more thresholds indicating the beginning of an action for the action sport to be analyzed. For example, a threshold for skiing may be three-quarters of a threshold for snowboarding. A threshold may be determined for an action sport by accumulating participant data and fitting two parameters for enhanced accuracy. For example, in snowboarding participant speed and jump duration may be fit to the participant data to eliminate false positives. For example, a participant may come to a sudden stop wherein the accelerometer variance drops to zero quickly as it may in a jump. The comparator 415 may determine that the participant speed has dropped to zero and may discard the generated start point as a false positive.

In some examples, there may be periods of loading time (e.g., a time in which preparatory activities leading up to initiation of an action occur, etc.) before an action begins. For example, there may be a period of time before a snowboarder leaves the ground in which the snowboarder begins to flip, spin, or pop off the ground. These periods of loading time may be useful in classifying or quantifying a trick. To compensate for these portions of data that may be missed during detection, the filter 140 may retain a portion of data before the start period for the action. For example, one half second of data may be back buffered. The comparator 415 may evaluate the retained portion of the data to determine if a squared magnitude for a timestamps in the retained portion of the data are outside a threshold and, if so, adjusts the generated start point using the evaluation. The comparator 415 may identify that a magnitude value for a data set of the plurality of data sets having a timestamp prior to the start point for the action is outside the threshold. The comparator 415 may adjust the start point for the action to the timestamp prior to the start point for the action. For example, the retained portion of the data may contain three consecutive timestamps before the generated start point where the squared magnitude exceeds the threshold and the start point may be moved to the first in time of the three timestamps.

After the filter 140 has determined the start point for an action, data may begin to accumulate. The filter 140 may continue to analyze incoming data using the decoder 410 and the comparator 415 to identify an end point for the action. The comparator 415 may identify that a magnitude value for a data set of the plurality of data sets having a timestamp prior to the start point for the action is outside the threshold. The comparator 415 may generate an end point for the action using the timestamp subsequent to the start point for the action. For example, the action may continue while the accelerometer magnitude remains outside a threshold and an end point may be generated for the action upon detecting that the accelerometer magnitude is outside the threshold. In some examples, the transformer 420 may begin to generate statistical data for the action. The transformer 420 may include a variety of components including a transceiver 425, a vector mapper 430, and a calculator 435.

The transceiver 425 may process incoming data such as the data provided by the multiplexer 115 and the filter 140 (e.g., as presented as output by the transceiver 405). The transceiver 425 may process data for output from the transformer 420. For example, the transceiver 425 may output data to a display (e.g., a display overlay for broadcast television, a webpage, a scoreboard, etc.). In some examples, a plurality of data sets from a data stream may be received from the sensor array 125. In an example, the plurality of data sets may be processed by the multiplexer 115 to include a timestamp corresponding with each data set of the plurality of data sets. In an example, the multiplexer 115 may process several data sets corresponding to the timestamp and output a single data set corresponding to the timestamp. For example, the multiplexer may receive an accelerometer value from a first receiver and a second receiver for a given timestamp and an accelerometer value from the second receiver for the given timestamp may be discarded. In some examples, the transceiver 425 may receive an indication (e.g., a flag, etc.) of a timestamp corresponding to a start point for an event from the filter 140. In some examples, the transceiver 425 may receive an indication (e.g., a flag, etc.) of a timestamp corresponding to an end point for an event from the filter 140.

Upon receiving the indication, the transformer 420 may invoke the vector mapper 430 to begin generating a vector map for data sets with timestamps on and after the start of the event. A plurality of data sets may be collected having timestamps subsequent to the start point for the action, upon identifying the start point for the action. For example, the vector mapper 430 may extract 3-axis magnitude data from accelerometer data, gyroscope data, and magnetometer data included in the data set to create a 9-axis data set for a timestamp. A vector map may be generated for the plurality of data sets having timestamps subsequent to the start point for the action. For example, the 9-axis data set may then be converted into a vector map. For example, the 9-axis data may be translated into quaternions (e.g., a four-dimensional vector space over real numbers) using an attitude heading reference system (AHRS) (e.g., providing pitch, roll, and yaw) yielding an absolute referenced position of a sporting device (e.g., snowboard, skateboard, etc.) with respect to gravity and earth's magnetic north at each timestamp. The quaternions may be used to compute Euler angles (e.g., orientation) for the sensor array's reference frame, and thus, the sporting device's reference frame. This may provide a complete position of the sporting device relative to a stationary point (e.g., an observer, etc.). The vector mapper 430 may include data collected from additional sensors in the vector maps. For example, GPS data and barometer data may be included in the vector maps.

The calculator 435 may analyze the vector maps produced by the vector mapper 430 to determine statistical values with regard to the sporting device. A set of statistical outputs may be calculated using the vector map. For example, the calculator 430 may calculate a vector distance between points in the vector map to determine a value. For some action sports more accurate calculations may be made by weighting data from one sensor over another. In an example, the plurality of data sets may include data collected from an accelerometer and data collected from a gyroscope and calculating a statistical output of the set of statistical outputs using the vector map may include applying a weighting coefficient to the data collected from the gyroscope. In some examples, the calculator 435 may use raw data received from one or more sensors of the sensor array in determining statistical values.

The calculator 430 may calculate a variety of statistical outputs such as, by way of example and not limitation:
Takeoff speed may be calculated using the last linear speed indicated from GPS data added in quadrature to a change in height and time derived from a complementary filter of a barometric pressure sensor and accelerometer, magnetometer, and gyroscope data included in the vector maps.
Takeoff force may be calculated using the magnitude of the accelerometer data at an instant before an action has started and may be quantified along each individual axis of the 3-axis accelerometer data.
Current spin angle may be calculated using a change in a spin Euler angle from the start of an action to the current time.
Current flip angle may be calculated using a change in a flip Euler angle from the start of an action to the current time.
Travel distance may be calculated using an integrated speed throughout the duration of the action multiplied by a time elapsed of each indicated speed.
Height may be calculated using a maximum height of a complementary filter of a barometric pressure sensor and accelerometer, magnetometer, and gyroscope data included in the vector maps as compared to a derived height at the start of an action.
Air time may be calculated using a change in timestamps from the start of the action to the current time.

Statistics such as, for example, takeoff speed and takeoff force may be calculated by the calculator upon receiving the indication of the start point of the action. Statistics such as, for example, spin angle, flip angle, travel distance, height, and air time may be calculated by the calculator 435 until an indication of the end point of the action is received. This may allow for classification and real-time or near-real time pattern recognition for specific actions. Statistics such as, for example, landing speed and landing force may be calculated by the calculator 435 upon receiving an indication of an end point of the action.

In some examples, the transceiver 425 may output the statistics for display on a display device. For example, the statistics may be output to a broadcast overlay applied to a live or recorded broadcast of a sporting event providing viewers with additional information about actions being performed by a participant. In some examples, the statistics may be output to a display device of a computing device. The information may be used by a participant or a coach to gain information about the performance of an action by the participant.

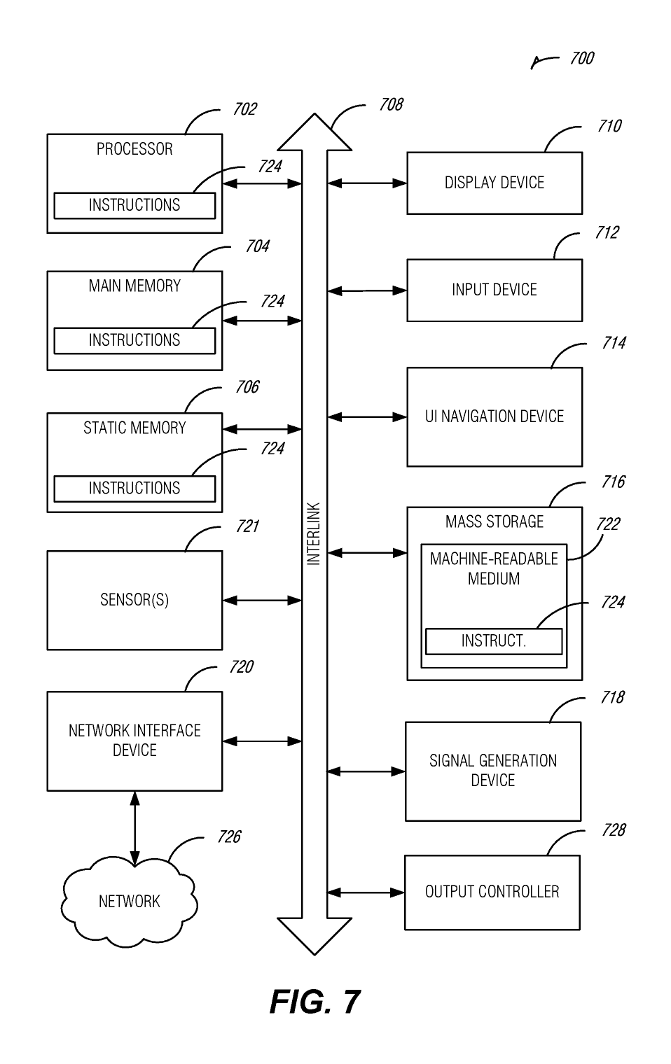

The present subject matter may be implemented in various configurations. For example, the multiplexer 115, the filter 140, the transceiver 405, the decoder 410, the comparator 415, the transformer 420, the transceiver 425, the vector mapper 430, and the calculator 435 may be implemented in different (or the same) computing systems (e.g., a single server, a collection of servers, a cloud-based computing platform, etc.). A computing system may comprise one or more processors (e.g., hardware processor 702 described in FIG. 7, etc.) that execute software instructions, such as those used to define a software or computer program, stored in a computer-readable storage medium such as a memory device (e.g., a main memory 704 and a static memory 706 as described in FIG. 7, a Flash memory, random access memory (RAM), or any other type of volatile or non-volatile memory that stores instructions), or a storage device (e.g., a disk drive, or an optical drive). Alternatively, the computing system may comprise dedicated hardware, such as one or more integrated circuits, one or more Application Specific Integrated Circuits (ASICs), one or more Application Specific Special Processors (ASSPs), one or more Field Programmable Gate Arrays (FPGAs), or any combination of the foregoing examples of dedicated hardware, for performing the techniques described in this disclosure.

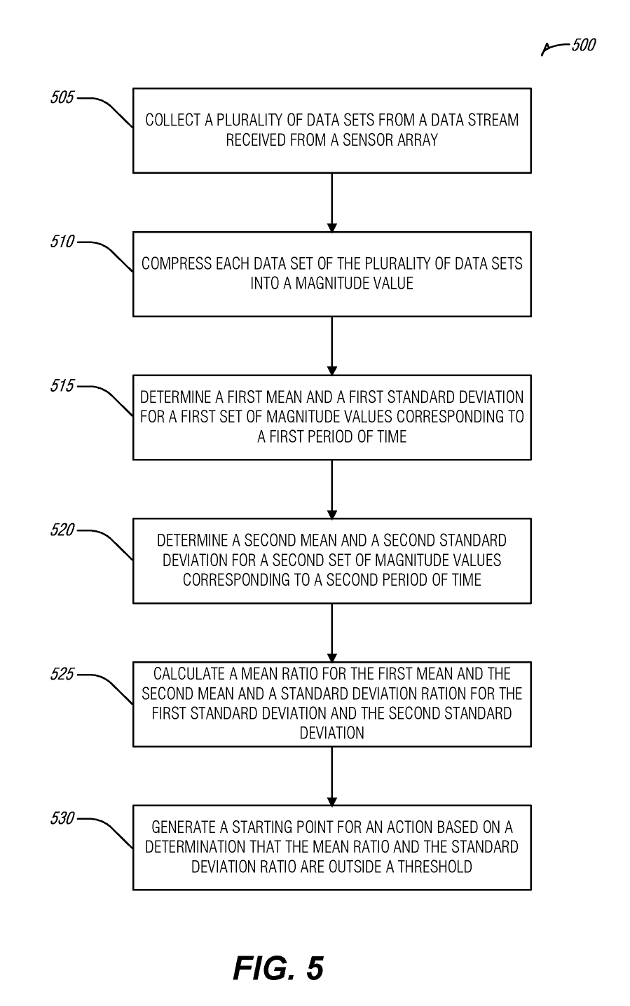

FIG. 5 illustrates a flowchart of an example of a method 500 for accelerated pattern matching in action sports, according to various embodiments. The method 500 may provide similar functionality as described in FIG. 4.

At operation 505, a plurality of data sets may be collected from a data stream received from a sensor array. Each data set of the plurality of data sets may correspond to a timestamp. The plurality of data sets may be collected from a first sensor of the senor array. In an example, the first sensor of the sensor array may be an accelerometer. In an example, the sensor array may include an accelerometer, a gyrometer, and a magnetometer. In an example, the sensor array may include a barometer. In an example, the sensor array may include a global positioning sensor (GPS).

At operation 510, each data set of the plurality of data sets may be compressed into a magnitude value. In an example, each data set of the plurality of data sets may be compressed by summing a square of a magnitude of a first axis, a square of a magnitude of a second axis, and a square of a magnitude of a third axis.

At operation 515, a first mean and a first standard deviation may be determined for a first set of magnitude values corresponding to a first period of time. At operation 520, a second mean and a second standard deviation may be determined for a second set of magnitude values corresponding to a second period of time. In an example, the first period of time may be greater than the second period of time. In an example, the first period of time may be one second and the second period of time may be less than thirty milliseconds.

At operation 525, a mean ratio may be calculated for the first mean and the second mean and a standard deviation ratio may be calculated for the first standard deviation and the second standard deviation.

At operation 530, a starting point may be generated for an action based on a determination that the mean ratio and the standard deviation ratio are outside a threshold. In some examples, it may be identified that a magnitude value for a data set of the plurality of data sets is outside the threshold. The data set may have a timestamp prior to the starting point for the action and the starting point may be adjusted for the action to the timestamp prior to the starting point for the action.

In some examples, a first plurality of means and a first plurality standard deviations may be determined for a first plurality of magnitude value sets. Each magnitude set of the first plurality of magnitude value sets may correspond to a first plurality of respective time periods. The plurality of respective time periods may be sequential and may begin prior to the first period of time. A second plurality of means and a second plurality standard deviations may be determined for a second plurality of magnitude value sets. Each magnitude set of the second plurality of magnitude value sets may correspond to a second plurality of respective time periods. The plurality of respective time periods may be sequential and may begin prior to the second period of time. A plurality of mean ratios may be calculated for respective of the first plurality of means and respective of the first plurality of standard deviations and a plurality of standard deviation ratios may be calculated for respective of the second plurality of means and respective of the second plurality of standard deviations. Identifying the starting point for the action may include a determination that the plurality of mean ratios and the plurality of standard deviation ratios are outside the first threshold.

In some examples, it may be identified that a magnitude value for a data set of the plurality of data sets is outside the threshold. The data set may have a timestamp subsequent to the starting point for the action and an ending point may be generated for the action using the timestamp subsequent to the starting point for the action.

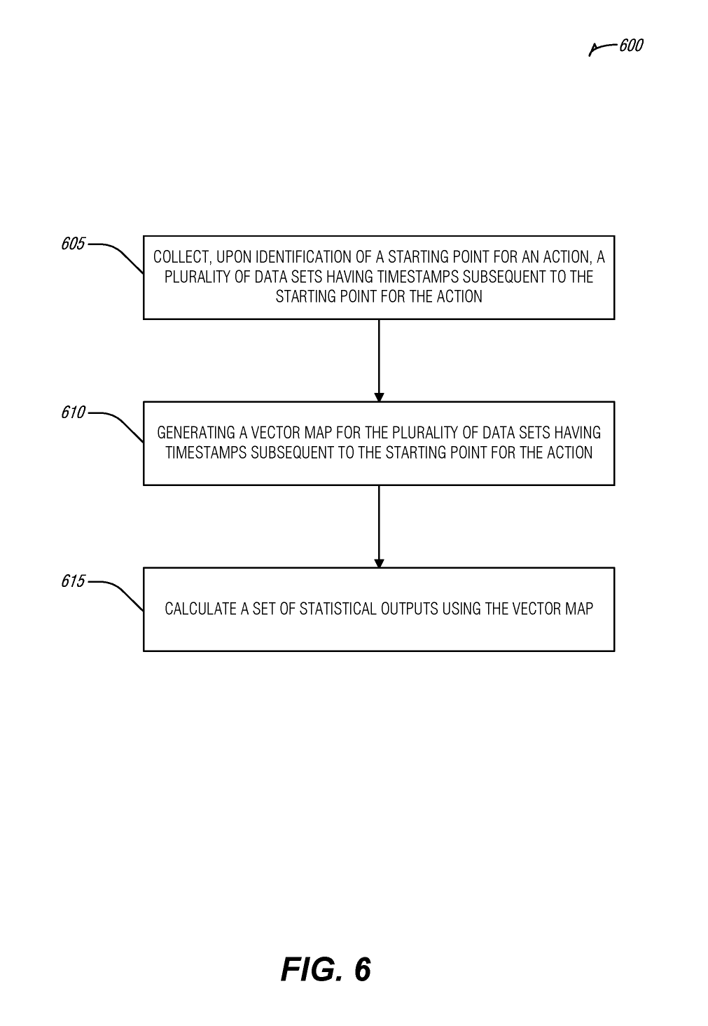

FIG. 6 illustrates a flowchart of an example of a method 600 for accelerated pattern matching in action sports, according to various embodiments.

At operation 605, a plurality of data sets may be collected having timestamps subsequent to a starting point for an action upon identifying the starting point for the action. In an example, the plurality of data sets may include data collected from an accelerometer and data collected from a gyroscope, and calculating a statistical output of the set of statistical outputs using the vector map may include applying a weighting coefficient to the data collected from the gyroscope.

At operation 610, a vector map may be generated for the plurality of data sets having timestamps subsequent to the starting point for the action.

At operation 615, a set of statistical outputs may be calculated using the vector map. In an example, the set of statistical outputs may include at least one of a takeoff speed, a takeoff force, a current spin angle, a current flip angle, a travel distance, a height, and an air time.

FIG. 7 illustrates a block diagram of an example machine 700 upon which any one or more of the techniques (e.g., methodologies) discussed herein may perform. In alternative embodiments, the machine 700 may operate as a standalone device or may be connected (e.g., networked) to other machines. In a networked deployment, the machine 700 may operate in the capacity of a server machine, a client machine, or both in server-client network environments. In an example, the machine 700 may act as a peer machine in peer-to-peer (P2P) (or other distributed) network environment. The machine 700 may be a personal computer (PC), a tablet PC, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic or a number of components, or mechanisms. Circuit sets are a collection of circuits implemented in tangible entities that include hardware (e.g., simple circuits, gates, logic, etc.). Circuit set membership may be flexible over time and underlying hardware variability. Circuit sets include members that may, alone or in combination, perform specified operations when operating. In an example, hardware of the circuit set may be immutably designed to carry out a specific operation (e.g., hardwired). In an example, the hardware of the circuit set may include variably connected physical components (e.g., execution units, transistors, simple circuits, etc.) including a computer readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuit set in hardware via the variable connections to carry out portions of the specific operation when in operation. Accordingly, the computer readable medium is communicatively coupled to the other components of the circuit set member when the device is operating. In an example, any of the physical components may be used in more than one member of more than one circuit set. For example, under operation, execution units may be used in a first circuit of a first circuit set at one point in time and reused by a second circuit in the first circuit set, or by a third circuit in a second circuit set at a different time.

Machine (e.g., computer system) 700 may include a hardware processor 702 (e.g., a central processing unit (CPU), a graphics processing unit (GPU), a hardware processor core, or any combination thereof), a main memory 704 and a static memory 706, some or all of which may communicate with each other via an interlink (e.g., bus) 708. The machine 700 may further include a display unit 710, an alphanumeric input device 712 (e.g., a keyboard), and a user interface (UI) navigation device 714 (e.g., a mouse). In an example, the display unit 710, input device 712 and UI navigation device 714 may be a touch screen display. The machine 700 may additionally include a storage device (e.g., drive unit) 716, a signal generation device 718 (e.g., a speaker), a network interface device 720, and one or more sensors 721, such as a global positioning system (GPS) sensor, compass, accelerometer, or other sensor. The machine 700 may include an output controller 728, such as a serial (e.g., Universal Serial Bus (USB), parallel, or other wired or wireless (e.g., infrared (IR), near field communication (NFC), etc.) connection to communicate or control one or more peripheral devices (e.g., a printer, card reader, etc.).

The storage device 716 may include a machine readable medium 722 on which is stored one or more sets of data structures or instructions 724 (e.g., software) embodying or utilized by any one or more of the techniques or functions described herein. The instructions 724 may also reside, completely or at least partially, within the main memory 704, within static memory 706, or within the hardware processor 702 during execution thereof by the machine 700. In an example, one or any combination of the hardware processor 702, the main memory 704, the static memory 706, or the storage device 716 may constitute machine readable media.

While the machine readable medium 722 is illustrated as a single medium, the term “machine readable medium” may include a single medium or multiple media (e.g., a centralized or distributed database, and/or associated caches and servers) configured to store the one or more instructions 724.

The term “machine readable medium” may include any medium that is capable of storing, encoding, or carrying instructions for execution by the machine 700 and that cause the machine 700 to perform any one or more of the techniques of the present disclosure, or that is capable of storing, encoding or carrying data structures used by or associated with such instructions. Non-limiting machine readable medium examples may include solid-state memories, and optical and magnetic media. In an example, a massed machine readable medium comprises a machine readable medium with a plurality of particles having invariant (e.g., rest) mass. Accordingly, massed machine-readable media are not transitory propagating signals. Specific examples of massed machine readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 724 may further be transmitted or received over a communications network 726 using a transmission medium via the network interface device 720 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the network interface device 720 may include one or more physical jacks (e.g., Ethernet, coaxial, or phone jacks) or one or more antennas to connect to the communications network 726. In an example, the network interface device 720 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 700, and includes digital or analog communications signals or other intangible medium to facilitate communication of such software.

### ADDITIONAL NOTES & EXAMPLES

Example 1 is a system for accelerated pattern recognition in action sports, the system comprising: one or more processors; a memory including instructions that, when executed by the one or more processors, cause the one or more processors to perform operations to: collect a plurality of data sets from a data stream received from a sensor array, each data set of the plurality of data sets corresponding to a timestamp; compress each data set of the plurality of data sets into a magnitude value; determine a first mean and a first standard deviation for a first set of magnitude values corresponding to a first period of time; determine a second mean and a second standard deviation for a second set of magnitude values corresponding to a second period of time; calculate a mean ratio for the first mean and the second mean and a standard deviation ratio for the first standard deviation and the second standard deviation; and generate a start point for an action based on a determination that the mean ratio and the standard deviation ratio are outside a threshold.

In Example 2, the subject matter of Example 1 optionally includes wherein the first period of time is greater than the second period of time.

In Example 3, the subject matter of any one or more of Examples 1-2 optionally include wherein the first period of time is one second and the second period of time is less than thirty milliseconds.

In Example 4, the subject matter of any one or more of Examples 1-3 optionally include wherein the instructions to compress each data set of the plurality of data sets includes instructions to sum a square of a magnitude of a first axis, a square of a magnitude of a second axis, and a square of a magnitude of a third axis.

In Example 5, the subject matter of any one or more of Examples 1-4 optionally include instructions that cause the one or more processors to perform operations to: determine a first plurality of means and a first plurality standard deviations for a first plurality of magnitude value sets, each magnitude set of the first plurality of magnitude value sets corresponding to a first plurality of respective time periods, the plurality of respective time periods being sequential and beginning prior to the first period of time; determine a second plurality of means and a second plurality standard deviations for a second plurality of magnitude value sets, each magnitude set of the second plurality of magnitude value sets corresponding to a second plurality of respective time periods, the plurality of respective time periods being sequential and beginning prior to the second period of time; and calculate a plurality of mean ratios for respective of the first plurality of means and respective of the first plurality of standard deviations and a plurality of standard deviation ratios for respective of the second plurality of means and respective of the second plurality of standard deviations, wherein identifying the start point for the action includes determining that the plurality of mean ratios and the plurality of standard deviation ratios are outside the threshold.

In Example 6, the subject matter of any one or more of Examples 1-5 optionally include instructions that cause the one or more processors to perform operations to: identify that a magnitude value for a data set of the plurality of data sets is outside the threshold, the data set having a timestamp prior to the start point for the action; and adjust the start point for the action to the timestamp prior to the start point for the action.

In Example 7, the subject matter of any one or more of Examples 1-6 optionally include instructions that cause the one or more processors to perform operations to: identify that a magnitude value for a data set of the plurality of data sets is outside the threshold, the data set having a timestamp subsequent to the start point for the action; and generate an end point for the action using the timestamp subsequent to the start point for the action.

In Example 8, the subject matter of any one or more of Examples 1-7 optionally include wherein the sensor array includes an accelerometer, a gyrometer, and a magnetometer.

In Example 9, the subject matter of any one or more of Examples 1-8 optionally include wherein the sensor array includes a barometer.

In Example 10, the subject matter of any one or more of Examples 1-9 optionally include wherein the sensor array includes a global positioning sensor (GPS).

In Example 11, the subject matter of any one or more of Examples 1-10 optionally include instructions that cause the one or more processors to perform operations to: collect, upon identifying the start point for the action, a plurality of data sets having timestamps subsequent to the start point for the action; generate a vector map for the plurality of data sets having timestamps subsequent to the start point for the action; and calculate a set of statistical outputs using the vector map.

In Example 12, the subject matter of Example 11 optionally includes wherein the plurality of data sets includes data collected from an accelerometer and data collected from a gyroscope, and wherein calculating a statistical output of the set of statistical outputs using the vector map includes applying a weighting coefficient to the data collected from the gyroscope.

In Example 13, the subject matter of any one or more of Examples 11-12 optionally include wherein the set of statistical outputs includes at least one of a takeoff speed, a takeoff force, a current spin angle, a current flip angle, a travel distance, a height, and an air time.

Example 14 is at least one computer readable medium including instructions for accelerated pattern recognition in action sports that, when executed by a machine, cause the machine to perform operations to: collect a plurality of data sets from a data stream received from a sensor array, each data set of the plurality of data sets corresponding to a timestamp; compress each data set of the plurality of data sets into a magnitude value; determine a first mean and a first standard deviation for a first set of magnitude values corresponding to a first period of time; determine a second mean and a second standard deviation for a second set of magnitude values corresponding to a second period of time; calculate a mean ratio for the first mean and the second mean and a standard deviation ratio for the first standard deviation and the second standard deviation; and generate a start point for an action based on a determination that the mean ratio and the standard deviation ratio are outside a threshold.

In Example 15, the subject matter of Example 14 optionally includes wherein the first period of time is greater than the second period of time.

In Example 16, the subject matter of any one or more of Examples 14-15 optionally include wherein the first period of time is one second and the second period of time is less than thirty milliseconds.

In Example 17, the subject matter of any one or more of Examples 14-16 optionally include wherein the instructions to compress each data set of the plurality of data sets includes instructions to sum a square of a magnitude of a first axis, a square of a magnitude of a second axis, and a square of a magnitude of a third axis.

In Example 18, the subject matter of any one or more of Examples 14-17 optionally include instructions that cause the machine to perform operations to: determine a first plurality of means and a first plurality standard deviations for a first plurality of magnitude value sets, each magnitude set of the first plurality of magnitude value sets corresponding to a first plurality of respective time periods, the plurality of respective time periods being sequential and beginning prior to the first period of time; determine a second plurality of means and a second plurality standard deviations for a second plurality of magnitude value sets, each magnitude set of the second plurality of magnitude value sets corresponding to a second plurality of respective time periods, the plurality of respective time periods being sequential and beginning prior to the second period of time; and calculate a plurality of mean ratios for respective of the first plurality of means and respective of the first plurality of standard deviations and a plurality of standard deviation ratios for respective of the second plurality of means and respective of the second plurality of standard deviations, wherein identifying the start point for the action includes determining that the plurality of mean ratios and the plurality of standard deviation ratios are outside the threshold.

In Example 19, the subject matter of any one or more of Examples 14-18 optionally include instructions that cause the machine to perform operations to: identify that a magnitude value for a data set of the plurality of data sets is outside the threshold, the data set having a timestamp prior to the start point for the action; and adjust the start point for the action to the timestamp prior to the start point for the action.

In Example 20, the subject matter of any one or more of Examples 14-19 optionally include instructions that cause the machine to perform operations to: identify that a magnitude value for a data set of the plurality of data sets is outside the threshold, the data set having a timestamp subsequent to the start point for the action; and generate an end point for the action using the timestamp subsequent to the start point for the action.

In Example 21, the subject matter of any one or more of Examples 14-20 optionally include wherein the sensor array includes an accelerometer, a gyrometer, and a magnetometer.

In Example 22, the subject matter of any one or more of Examples 14-21 optionally include wherein the sensor array includes a barometer.

In Example 23, the subject matter of any one or more of Examples 14-22 optionally include wherein the sensor array includes a global positioning sensor (GPS).

In Example 24, the subject matter of any one or more of Examples 14-23 optionally include instructions that cause the machine to perform operations to: collect, upon identifying the start point for the action, a plurality of data sets having timestamps subsequent to the start point for the action; generate a vector map for the plurality of data sets having timestamps subsequent to the start point for the action; and calculate a set of statistical outputs using the vector map.

In Example 25, the subject matter of Example 24 optionally includes wherein the plurality of data sets includes data collected from an accelerometer and data collected from a gyroscope, and wherein calculating a statistical output of the set of statistical outputs using the vector map includes applying a weighting coefficient to the data collected from the gyroscope.

In Example 26, the subject matter of any one or more of Examples 24-25 optionally include wherein the set of statistical outputs includes at least one of a takeoff speed, a takeoff force, a current spin angle, a current flip angle, a travel distance, a height, and an air time.

Example 27 is a method for accelerated pattern recognition in action sports, the method comprising: collecting a plurality of data sets from a data stream received from a sensor array, each data set of the plurality of data sets corresponding to a timestamp; compressing each data set of the plurality of data sets into a magnitude value; determining a first mean and a first standard deviation for a first set of magnitude values corresponding to a first period of time; determining a second mean and a second standard deviation for a second set of magnitude values corresponding to a second period of time; calculating a mean ratio for the first mean and the second mean and a standard deviation ratio for the first standard deviation and the second standard deviation; and generating a start point for an action based on a determination that the mean ratio and the standard deviation ratio are outside a threshold.

In Example 28, the subject matter of Example 27 optionally includes wherein the first period of time is greater than the second period of time.

In Example 29, the subject matter of any one or more of Examples 27-28 optionally include wherein the first period of time is one second and the second period of time is less than thirty milliseconds.

In Example 30, the subject matter of any one or more of Examples 27-29 optionally include wherein compressing each data set of the plurality of data sets includes summing a square of a magnitude of a first axis, a square of a magnitude of a second axis, and a square of a magnitude of a third axis.

In Example 31, the subject matter of any one or more of Examples 27-30 optionally include determining a first plurality of means and a first plurality standard deviations for a first plurality of magnitude value sets, each magnitude set of the first plurality of magnitude value sets corresponding to a first plurality of respective time periods, the plurality of respective time periods being sequential and beginning prior to the first period of time; determining a second plurality of means and a second plurality standard deviations for a second plurality of magnitude value sets, each magnitude set of the second plurality of magnitude value sets corresponding to a second plurality of respective time periods, the plurality of respective time periods being sequential and beginning prior to the second period of time; and calculating a plurality of mean ratios for respective of the first plurality of means and respective of the first plurality of standard deviations and a plurality of standard deviation ratios for respective of the second plurality of means and respective of the second plurality of standard deviations, wherein identifying the start point for the action includes determining that the plurality of mean ratios and the plurality of standard deviation ratios are outside the threshold.

In Example 32, the subject matter of any one or more of Examples 27-31 optionally include identifying that a magnitude value for a data set of the plurality of data sets is outside the threshold, the data set having a timestamp prior to the start point for the action; and adjusting the start point for the action to the timestamp prior to the start point for the action.

In Example 33, the subject matter of any one or more of Examples 27-32 optionally include identifying that a magnitude value for a data set of the plurality of data sets is outside the threshold, the data set having a timestamp subsequent to the start point for the action; and generating an end point for the action using the timestamp subsequent to the start point for the action.

In Example 34, the subject matter of any one or more of Examples 27-33 optionally include wherein the sensor array includes an accelerometer, a gyrometer, and a magnetometer.

In Example 35, the subject matter of any one or more of Examples 27-34 optionally include wherein the sensor array includes a barometer.

In Example 36, the subject matter of any one or more of Examples 27-35 optionally include wherein the sensor array includes a global positioning sensor (GPS).

In Example 37, the subject matter of any one or more of Examples 27-36 optionally include collecting, upon identifying the start point for the action, a plurality of data sets having timestamps subsequent to the start point for the action; generating a vector map for the plurality of data sets having timestamps subsequent to the start point for the action; and calculating a set of statistical outputs using the vector map.

In Example 38, the subject matter of Example 37 optionally includes wherein the plurality of data sets includes data collected from an accelerometer and data collected from a gyroscope, and wherein calculating a statistical output of the set of statistical outputs using the vector map includes applying a weighting coefficient to the data collected from the gyroscope.

In Example 39, the subject matter of any one or more of Examples 37-38 optionally include wherein the set of statistical outputs includes at least one of a takeoff speed, a takeoff force, a current spin angle, a current flip angle, a travel distance, a height, and an air time.

Example 40 is a system to implement accelerated pattern recognition in action sports, the system comprising means to perform any method of Examples 27-39.

Example 41 is at least one machine readable medium to implement accelerated pattern recognition in action sports, the machine readable medium including instructions that, when executed by a machine, cause the machine to perform any method of Examples 27-39.

Example 42 is a system for accelerated pattern recognition in action sports, the system comprising: means for collecting a plurality of data sets from a data stream received from a sensor array, each data set of the plurality of data sets corresponding to a timestamp; means for compressing each data set of the plurality of data sets into a magnitude value; means for determining a first mean and a first standard deviation for a first set of magnitude values corresponding to a first period of time; means for determining a second mean and a second standard deviation for a second set of magnitude values corresponding to a second period of time; means for calculating a mean ratio for the first mean and the second mean and a standard deviation ratio for the first standard deviation and the second standard deviation; and means for generating a start point for an action based on a determination that the mean ratio and the standard deviation ratio are outside a threshold.

In Example 43, the subject matter of Example 42 optionally includes wherein the first period of time is greater than the second period of time.

In Example 44, the subject matter of any one or more of Examples 42-43 optionally include wherein the first period of time is one second and the second period of time is less than thirty milliseconds.

In Example 45, the subject matter of any one or more of Examples 42-44 optionally include wherein compressing each data set of the plurality of data sets includes summing a square of a magnitude of a first axis, a square of a magnitude of a second axis, and a square of a magnitude of a third axis.

In Example 46, the subject matter of any one or more of Examples 42-45 optionally include means for determining a first plurality of means and a first plurality standard deviations for a first plurality of magnitude value sets, each magnitude set of the first plurality of magnitude value sets corresponding to a first plurality of respective time periods, the plurality of respective time periods being sequential and beginning prior to the first period of time; means for determining a second plurality of means and a second plurality standard deviations for a second plurality of magnitude value sets, each magnitude set of the second plurality of magnitude value sets corresponding to a second plurality of respective time periods, the plurality of respective time periods being sequential and beginning prior to the second period of time; and means for calculating a plurality of mean ratios for respective of the first plurality of means and respective of the first plurality of standard deviations and a plurality of standard deviation ratios for respective of the second plurality of means and respective of the second plurality of standard deviations, wherein identifying the start point for the action includes determining that the plurality of mean ratios and the plurality of standard deviation ratios are outside the threshold.

In Example 47, the subject matter of any one or more of Examples 42-46 optionally include means for identifying that a magnitude value for a data set of the plurality of data sets is outside the threshold, the data set having a timestamp prior to the start point for the action; and means for adjusting the start point for the action to the timestamp prior to the start point for the action.

In Example 48, the subject matter of any one or more of Examples 42-47 optionally include means for identifying that a magnitude value for a data set of the plurality of data sets is outside the threshold, the data set having a timestamp subsequent to the start point for the action; and means for generating an end point for the action using the timestamp subsequent to the start point for the action.

In Example 49, the subject matter of any one or more of Examples 42-48 optionally include wherein the sensor array includes an accelerometer, a gyrometer, and a magnetometer.

In Example 50, the subject matter of any one or more of Examples 42-49 optionally include wherein the sensor array includes a barometer.

In Example 51, the subject matter of any one or more of Examples 42-50 optionally include wherein the sensor array includes a global positioning sensor (GPS).

In Example 52, the subject matter of any one or more of Examples 42-51 optionally include means for collecting, upon identifying the start point for the action, a plurality of data sets having timestamps subsequent to the start point for the action; means for generating a vector map for the plurality of data sets having timestamps subsequent to the start point for the action; and means for calculating a set of statistical outputs using the vector map.

In Example 53, the subject matter of Example 52 optionally includes wherein the plurality of data sets includes data collected from an accelerometer and data collected from a gyroscope, and wherein calculating a statistical output of the set of statistical outputs using the vector map includes applying a weighting coefficient to the data collected from the gyroscope.

In Example 54, the subject matter of any one or more of Examples 52-53 optionally include wherein the set of statistical outputs includes at least one of a takeoff speed, a takeoff force, a current spin angle, a current flip angle, a travel distance, a height, and an air time.

What is claimed is:

1. A system for accelerated pattern recognition in action sports, the system comprising:
one or more processors;
a memory including instructions that, when executed by the one or more processors, cause the one or more processors to perform operations to:
collect a plurality of data sets from a data stream received from a sensor array, each data set of the plurality of data sets corresponding to a timestamp;
compress each data set of the plurality of data sets into a magnitude value;
determine a first mean and a first standard deviation for a first set of magnitude values corresponding to a first period of time;
determine a second mean and a second standard deviation for a second set of magnitude values corresponding to a second period of time;
calculate a mean ratio for the first mean and the second mean and a standard deviation ratio for the first standard deviation and the second standard deviation; and
generate a start point for an action based on a determination that the mean ratio and the standard deviation ratio are outside a threshold.

2. The system of claim 1, wherein the first period of time is greater than the second period of time.

3. The system of claim 1, wherein the instructions to compress each data set of the plurality of data sets includes instructions to sum a square of a magnitude of a first axis, a square of a magnitude of a second axis, and a square of a magnitude of a third axis.

4. The system of claim 1, further comprising instructions that cause the one or more processors to perform operations to:
determine a first plurality of means and a first plurality standard deviations for a first plurality of magnitude value sets, each magnitude set of the first plurality of magnitude value sets corresponding to a first plurality of respective time periods, the plurality of respective time periods being sequential and beginning prior to the first period of time;
determine a second plurality of means and a second plurality standard deviations for a second plurality of magnitude value sets, each magnitude set of the second plurality of magnitude value sets corresponding to a second plurality of respective time periods, the plurality of respective time periods being sequential and beginning prior to the second period of time; and
calculate a plurality of mean ratios for respective of the first plurality of means and respective of the first plurality of standard deviations and a plurality of standard deviation ratios for respective of the second plurality of means and respective of the second plurality of standard deviations, wherein identifying the start point for the action includes determining that the plurality of mean ratios and the plurality of standard deviation ratios are outside the threshold.

5. The system of claim 1, further comprising instructions that cause the one or more processors to perform operations to:
identify that a magnitude value for a data set of the plurality of data sets is outside the threshold, the data set having a timestamp prior to the start point for the action; and
adjust the start point for the action to the timestamp prior to the start point for the action.

6. The system of claim 1, further comprising instructions that cause the one or more processors to perform operations to:
identify that a magnitude value for a data set of the plurality of data sets is outside the threshold, the data set having a timestamp subsequent to the start point for the action; and
generate an end point for the action using the timestamp subsequent to the start point for the action.

7. The system of claim 1, further comprising instructions that cause the one or more processors to perform operations to:
collect, upon identifying the start point for the action, a plurality of data sets having timestamps subsequent to the start point for the action;
generate a vector map for the plurality of data sets having timestamps subsequent to the start point for the action; and
calculate a set of statistical outputs using the vector map.

8. At least one computer readable medium including instructions for accelerated pattern recognition in action sports that, when executed by a machine, cause the machine to perform operations to:
collect a plurality of data sets from a data stream received from a sensor array, each data set of the plurality of data sets corresponding to a timestamp;
compress each data set of the plurality of data sets into a magnitude value;
determine a first mean and a first standard deviation for a first set of magnitude values corresponding to a first period of time;
determine a second mean and a second standard deviation for a second set of magnitude values corresponding to a second period of time;
calculate a mean ratio for the first mean and the second mean and a standard deviation ratio for the first standard deviation and the second standard deviation; and
generate a start point for an action based on a determination that the mean ratio and the standard deviation ratio are outside a threshold.

9. The at least one computer readable medium of claim 8, wherein the first period of time is greater than the second period of time.

10. The at least one computer readable medium of claim 8, wherein the instructions to compress each data set of the plurality of data sets includes instructions to sum a square of a magnitude of a first axis, a square of a magnitude of a second axis, and a square of a magnitude of a third axis.

11. The at least one computer readable medium of claim 8, further comprising instructions that cause the machine to perform operations to:
determine a first plurality of means and a first plurality standard deviations for a first plurality of magnitude value sets, each magnitude set of the first plurality of magnitude value sets corresponding to a first plurality of respective time periods, the plurality of respective time periods being sequential and beginning prior to the first period of time;
determine a second plurality of means and a second plurality standard deviations for a second plurality of magnitude value sets, each magnitude set of the second plurality of magnitude value sets corresponding to a second plurality of respective time periods, the plurality of respective time periods being sequential and beginning prior to the second period of time; and
calculate a plurality of mean ratios for respective of the first plurality of means and respective of the first plurality of standard deviations and a plurality of standard deviation ratios for respective of the second plurality of means and respective of the second plurality of standard deviations, wherein identifying the start point for the action includes determining that the plurality of mean ratios and the plurality of standard deviation ratios are outside the threshold.

12. The at least one computer readable medium of claim 8, further comprising instructions that cause the machine to perform operations to:
identify that a magnitude value for a data set of the plurality of data sets is outside the threshold, the data set having a timestamp prior to the start point for the action; and
adjust the start point for the action to the timestamp prior to the start point for the action.

13. The at least one computer readable medium of claim 8, further comprising instructions that cause the machine to perform operations to:
identify that a magnitude value for a data set of the plurality of data sets is outside the threshold, the data set having a timestamp subsequent to the start point for the action; and
generate an end point for the action using the timestamp subsequent to the start point for the action.

14. The at least one computer readable medium of claim 8, further comprising instructions that cause the machine to perform operations to:
collect, upon identifying the start point for the action, a plurality of data sets having timestamps subsequent to the start point for the action;
generate a vector map for the plurality of data sets having timestamps subsequent to the start point for the action; and
calculate a set of statistical outputs using the vector map.

15. A method for accelerated pattern recognition in action sports, the method comprising:
collecting a plurality of data sets from a data stream received from a sensor array, each data set of the plurality of data sets corresponding to a timestamp;
compressing each data set of the plurality of data sets into a magnitude value;
determining a first mean and a first standard deviation for a first set of magnitude values corresponding to a first period of time;
determining a second mean and a second standard deviation for a second set of magnitude values corresponding to a second period of time;
calculating a mean ratio for the first mean and the second mean and a standard deviation ratio for the first standard deviation and the second standard deviation; and
generating a start point for an action based on a determination that the mean ratio and the standard deviation ratio are outside a threshold.

16. The method of claim 15, wherein the first period of time is greater than the second period of time.

17. The method of claim 15, wherein compressing each data set of the plurality of data sets includes summing a square of a magnitude of a first axis, a square of a magnitude of a second axis, and a square of a magnitude of a third axis.

18. The method of claim 15, further comprising:
determining a first plurality of means and a first plurality standard deviations for a first plurality of magnitude value sets, each magnitude set of the first plurality of magnitude value sets corresponding to a first plurality of respective time periods, the plurality of respective time periods being sequential and beginning prior to the first period of time;
determining a second plurality of means and a second plurality standard deviations for a second plurality of magnitude value sets, each magnitude set of the second plurality of magnitude value sets corresponding to a second plurality of respective time periods, the plurality of respective time periods being sequential and beginning prior to the second period of time; and
calculating a plurality of mean ratios for respective of the first plurality of means and respective of the first plurality of standard deviations and a plurality of standard deviation ratios for respective of the second plurality of means and respective of the second plurality of standard deviations, wherein identifying the start point for the action includes determining that the plurality of mean ratios and the plurality of standard deviation ratios are outside the threshold.

19. The method of claim 15, further comprising:
identifying that a magnitude value for a data set of the plurality of data sets is outside the threshold, the data set having a timestamp prior to the start point for the action; and
adjusting the start point for the action to the timestamp prior to the start point for the action.

20. The method of claim 15, further comprising:
identifying that a magnitude value for a data set of the plurality of data sets is outside the threshold, the data set having a timestamp subsequent to the start point for the action; and
generating an end point for the action using the timestamp subsequent to the start point for the action.

21. The method of claim 15, further comprising:
collecting, upon identifying the start point for the action, a plurality of data sets having timestamps subsequent to the start point for the action;
generating a vector map for the plurality of data sets having timestamps subsequent to the start point for the action; and
calculating a set of statistical outputs using the vector map.
